(19) United States
(12) Patent Application Publication
(10) Pub. No.: US 2024/0047407 A1
(43) Pub. Date: Feb. 8, 2024

(54) INTEGRATED CIRCUIT PACKAGE

(71) Applicant: STMicroelectronics (Grenoble 2) SAS, Grenoble (FR)

(72) Inventors: Younes BOUTALEB, Grenoble (FR); Julien CUZZOCREA, Montbonnot Saint Martin (FR); Romain COFFY, Voiron (FR)

(73) Assignee: STMicroelectronics (Grenoble 2) SAS, Grenoble (FR)

(21) Appl. No.: 18/228,898

(22) Filed: Aug. 1, 2023

(30) Foreign Application Priority Data
Aug. 3, 2022 (FR) 2208049

(51) Int. Cl. H01L 23/00

(52) U.S. Cl. CPC H01L 24/30; H01L 24/29; H01L 24/27; H01L 24/94; H01L 24/32; H01L 24/73; H01L 2224/73265; H01L 24/48; H01L 2224/48221; H01L 2224/48091; H01L 2224/94; H01L 2224/27848; H01L 2224/27416; H01L 2224/2761; H01L 2224/29012; H01L 2224/29011; H01L 2224/32221; H01L 2224/30051; H01L 2224/3003; H01L 2224/30505

(57) ABSTRACT

An integrated circuit package includes at least one electronic chip having a first face fastened onto a first face of a carrier substrate by an adhesive interface. The adhesive interface includes a crown formed of a first adhesive material that is fastened on the periphery of the first face of the electronic chip. The crown defining an internal housing. A second adhesive material, different than the first material, is deposited in the internal housing.

### PRIORITY CLAIM

This application claims the priority benefit of French Application for Patent No. 2208049, filed on Aug. 3, 2022, the content of which is hereby incorporated by reference in its entirety to the maximum extent allowable by law.

### TECHNICAL FIELD

Embodiments and implementations of the present invention relate to the field of microelectronics, in particular the field of packaging integrated circuits, and more particularly the integrated circuit packages of the Wire Bonding-Ball Grid Array type, routinely designated by a person skilled in the art by the acronym WB-BGA.

### BACKGROUND

WB-BGA packages include a support substrate supporting on a first face, typically the upper face, an electronic integrated circuit chip and bonding wires are soldered between contact pads of the upper face of the electronic chip and contact pads of this first face of the support substrate.

The support substrate includes on a second face, typically a lower face, a ball grid array intended to be soldered onto a printed circuit having dedicated receiving pads.

The electronic chip is fastened onto the first face of the support substrate via a glue.

However, during the fastening of the chip onto the first face of the support substrate, a part of the glue can rise along the vertical edges of the chip until it possibly reaches the contact pads intended to receive the bonding wires.

Moreover, this overflowing and rising part of glue has an irregular shape.

All this can lead to a contamination of the contact pads intended to receive the bonding wires as well as strong stresses on the dielectric layers with a low dielectric constant (low-k) contained in the chip.

To overcome these disadvantages, it was considered to reduce the quantity of glue but this leads to insufficient coverage of the lower face of the chip by the glue favoring the creation of cracks.

There is therefore a need to more effectively overcome the disadvantages mentioned above.

### SUMMARY

According to one aspect, an integrated circuit package is proposed comprising at least one electronic chip having a first face, typically the lower face, fastened onto a first face, typically the upper face, of a carrier substrate by an adhesive interface.

This adhesive interface includes a crown containing a first adhesive material and fastened on the periphery of the first face of the electronic chip and defining an internal housing containing a second adhesive material different than the first material.

Thus, instead of using a single standard glue to fasten the chip onto the carrier substrate, two different adhesive materials are used here.

A first material forms a crown allowing on the one hand to control the thickness between the chip and the carrier substrate well, and on the other hand to house a second adhesive material which because of the presence of this crown does not rise on the vertical edges of the chip.

Moreover, these two materials form an adhesive interface allowing to effectively fasten the chip onto the carrier substrate while minimizing the risk of appearance of cracks under the chip, in particular when the second material covers at least between 80% and 90% of the surface of the first face of the electronic chip.

The second material can be a glue such as a conventional glue, and the first material forming said crown can be an adhesive film or a filling material, known to a person skilled in the art under the name “underfill”.

The crown can include at least one lateral opening, which allows in certain cases to be able to evacuate a possible overpressure of air during the filling of the internal housing by the second material during the manufacturing of the package.

According to another aspect, a method is proposed for manufacturing at least one integrated circuit package, comprising the following steps: a) Fastening on the periphery of a first face of an electronic chip a crown containing a first adhesive material and defining an internal housing, b) Disposing a second adhesive material different than the first material in said housing, the crown of first material and the second material forming an adhesive interface, and c) Fastening said first face of the electronic chip onto a first face of a carrier substrate via the adhesive interface.

According to one embodiment, the steps a), b) and c) comprise: providing a semiconductor wafer; thinning the wafer by a first thickness starting from an initial face of this wafer so as to obtain a thinned wafer having a first face; forming on the first face of the thinned wafer a layer of the first material; local etchings of the layer of first material so as to form local crowns; forming in the wafer electronic chips respectively in contact on their periphery with the corresponding local crowns; individualizing the electronic chips equipped on their first face with the corresponding local crowns respectively forming internal housings; disposing in each internal housing the second adhesive material; and fastening each chip onto a respective carrier substrate via the corresponding adhesive interface.

As indicated above, the second material can be a glue and the first material can be an adhesive film or a filling material.

According to one embodiment, in step b), a second adhesive material is disposed in said housing so that the second material covers at least between 80% and 90% of the surface of the first face of the electronic chip.

According to one embodiment, the method can further comprise a formation of at least one lateral opening in the crown.

### BRIEF DESCRIPTION OF THE DRAWINGS

Other advantages and features of the invention will appear upon examination of the detailed description of implementations and embodiments, in no way limiting, and of the appended drawings in which:

FIG. 1 illustrates a cross-section of an integrated circuit package;

FIG. 2 is a cross-section of the package shown in FIG. 1 along the line II-II; and

FIGS. 3 to 8 illustrate an embodiment of a method for creating the package shown in FIGS. 1-2.

### DETAILED DESCRIPTION

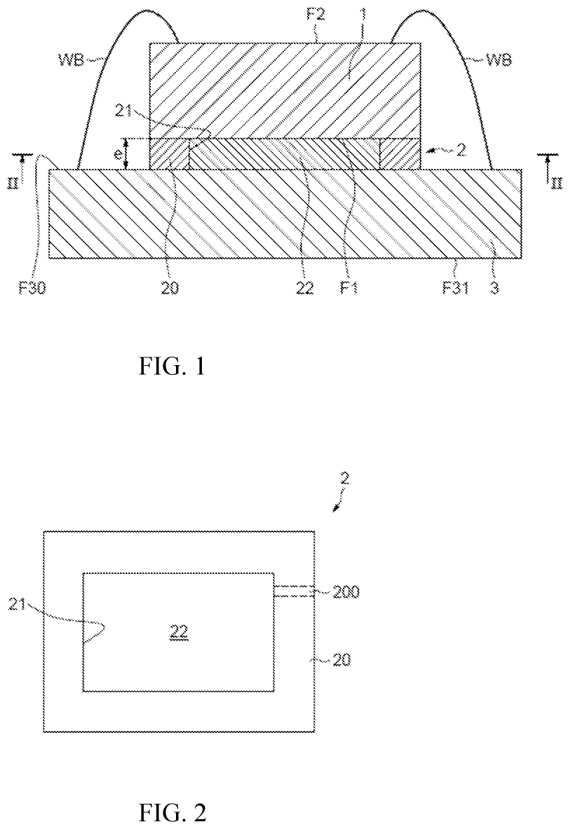

In FIG. 1, the reference BT designates an integrated circuit package.

This package comprises a carrier substrate 3 including a first face or upper face F30 and a second face or lower face F31.

The lower face F31 is intended to support a ball grid array (not shown here for simplification purposes) intended to be soldered onto a printed circuit board.

The first face or upper face F30 of the carrier substrate supports an electronic integrated circuit chip 1, a first face, or lower face, F1 of which is fastened onto the first face F30 of the carrier substrate via an adhesive interface 2.

The chip 1 also includes a second face, or upper face, F2 onto contacts pads of which bonding wires WB connecting these contacts pads to contact pads located on the first face F30 of the carrier substrate 30 are soldered.

The adhesive interface 2 has a thickness e, for example between 30 microns and 50 microns.

As illustrated in FIG. 1 and also in FIG. 2 which is a cross-section along the line II-II of FIG. 1, this adhesive interface includes a crown 20 containing a first adhesive material.

This crown 20 is fastened onto the periphery of the first face F1 of the electronic chip.

It defines an internal housing 21 containing a second adhesive material 22.

The first adhesive material 20 and the second adhesive material 22 are different materials.

For example, the first adhesive material of the crown 20 can be a dielectric film such as the film marketed by the Japanese company Ajinomoto under the acronym ABF (Ajinomoto Build-up Film).

Alternatively, this first material of the crown 20 can be a filling material known to a person skilled in the art as an “underfill” material.

The second material 22 contained in the internal housing 21 can be a conventional glue that preferably covers at least 80 to 90% of the surface of the first face F1 of the electronic chip. In other words, the internal housing 21 defined (delimited) by the crown 20 exposes at least 80 to 90% of the surface of the first face F1 of the electronic chip and the second material 22 substantially covers that surface.

The crown 20 allows to effectively control the value of the thickness e separating the first face F1 of the chip from the first face F30 of the carrier substrate.
Moreover, this crown traps the glue 22 and avoids it rising along the vertical edges of the chip during the creation of the package.

Moreover, the volume of glue chosen in such a way that the glue covers at least 80 to 90% of the first face F1 of the chip allows, in combination with the adhesive crown 20, to obtain good adhesion of the chip onto the substrate while minimizing the risk of appearance of cracks under the chip.

Furthermore, as illustrated in FIG. 2, the crown 20 can comprise a lateral opening 200 which allows, if necessary, the evacuation of an overpressure of air during the operation of fastening of the chip onto the substrate.

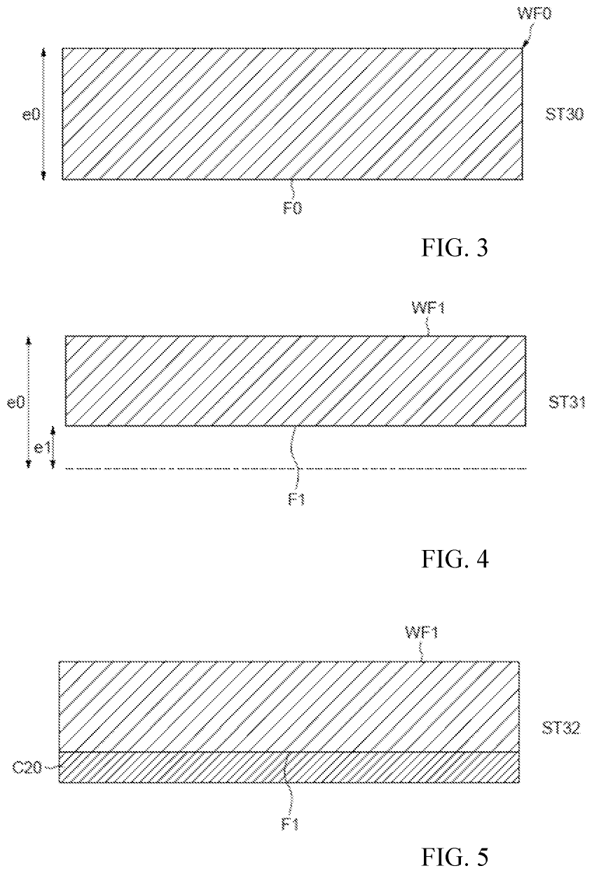

Reference is now made more particularly to FIGS. 3 to 8 to illustrate an embodiment of a method for creating the package BT.

In the step ST30 of FIG. 3, a semiconductor wafer is provided, WF0 having an initial thickness e0 and an initial lower face F0.

Then, in step ST31 of FIG. 4, the wafer WF0 is thinned, in a manner conventional and known per se, from the initial face F0 over a thickness e1 so that the difference e0−e1 corresponds to the desired thickness of the integrated circuit chips that will be created in this wafer.

A thinned wafer WF1 having a first face or lower face F1 is thus obtained.

Then, in step ST32 of FIG. 5, a layer C20 of the first material is formed on the first face F1.

For example, in the case in which the first material is a dielectric film, for example an ABF film, this film, originally soft, is deposited on the first face F1 then solidified by thermal annealing at a temperature, for example, between 150° C. and 200° C.

In the case in which the first material is a filling material, the latter is deposited in a liquid manner, for example via a spin coater, then solidified also by thermal annealing at a temperature between 150° C. and 180° C. for one to two hours.

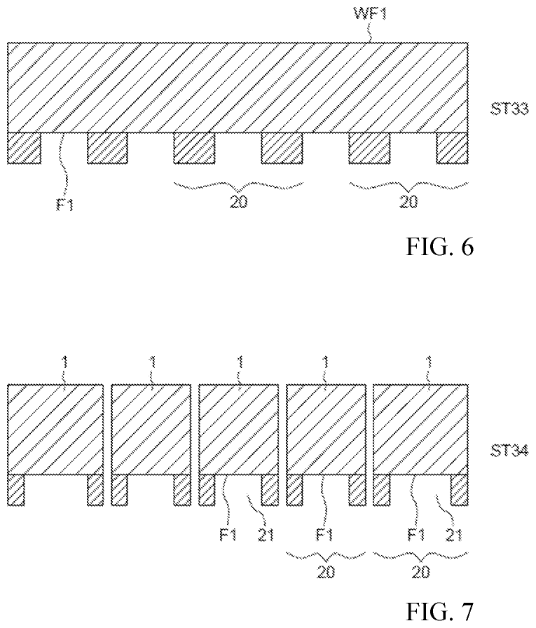

Then, in step ST33 of FIG. 6, local etchings of the layer C20 of the first material are carried out so as to form local crowns 20, optionally equipped with the lateral openings.

Alternatively, in the case of the use of the filling material, it is possible to apply onto the first face F1 local molds having the shapes of the local crowns 20, inject the filling material into the molds, solidify the injected material by baking as mentioned above then remove the molds.

Then, in step ST34 of FIG. 7, the various integrated circuits or chips 1 that are then individualized, conventionally by sawing (a process referred to in the art as singulating), so as to obtain electronic chips 1 equipped on their first face F1 with the corresponding crowns respectively forming internal housings 21 are made, in a manner conventional and known per se, inside the semiconductor wafer WF1 equipped with these local crowns.

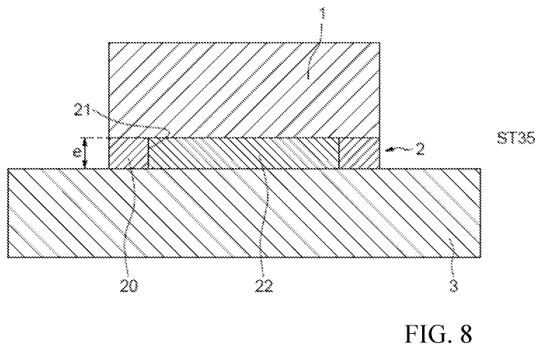

Then, each internal housing 21 is filled with the appropriate volume of glue 22 and, as illustrated in FIG. 8, in step ST35, the chip is fastened, by compression, onto the carrier substrate 3 via the adhesive interface 2 which in the end has the thickness e mentioned in FIG. 1.

1. An integrated circuit package, comprising:
a carrier substrate; and
an electronic integrated circuit chip having a first face fastened onto a first face of the carrier substrate by an adhesive interface;
wherein said adhesive interface comprises:
a crown formed by a first adhesive material and fastened on a periphery of the first face of the electronic chip and defining an internal housing; and
a second adhesive material different than the first adhesive material contained within the internal housing.

2. The package according to claim 1, wherein the first adhesive material is an adhesive film, and wherein the second adhesive material is a glue.

3. The package according to claim 1, wherein the first adhesive material is a filling material, and wherein the second adhesive material is a glue.

4. The package according to claim 1, wherein the second adhesive material covers at least between 80% and 90% of a surface of said first face of the electronic integrated circuit chip.

5. The package according to claim 1, wherein the internal housing exposes at least between 80% and 90% of a surface of said first face of the electronic integrated circuit chip and the second adhesive substantially covers said surface which is exposed.

6. The package according to claim 1, wherein the crown includes at least one lateral opening from the internal housing to an outer surface of the crown.

7. A method for manufacturing at least one integrated circuit package, comprising:
a) fastening a crown formed of a first adhesive material on a periphery of a first face of an electronic integrated circuit chip, wherein said crown defines an internal housing;
b) disposing a second adhesive material different than the first material within said internal housing, the crown formed of the first adhesive material and the second adhesive material forming an adhesive interface; and
c) fastening said first face of the electronic integrated circuit chip onto a first face of a carrier substrate via the adhesive interface.

8. The method according to claim 7, wherein the first adhesive material is an adhesive film, and wherein the second adhesive material is a glue.

9. The method according to claim 7, wherein the first adhesive material is a filling material, and wherein the second adhesive material is a glue.

10. The method according to claim 7, wherein the second adhesive material covers at least between 80% and 90% of a surface of said first face of the electronic integrated circuit chip.

11. The method according to claim 7, wherein the internal housing exposes at least between 80% and 90% of a surface of said first face of the electronic integrated circuit chip and the second adhesive substantially covers the exposed surface.

12. The method according to claim 7, further comprising forming at least one lateral opening in the crown, wherein each lateral opening extends from the internal housing to an outer surface of the crown.

13. A method, comprising:
providing a semiconductor wafer;
thinning the semiconductor wafer by a first thickness starting from an initial face of the semiconductor wafer so as to obtain a thinned semiconductor wafer having a first face;
forming a layer of a first adhesive material on the first face of the thinned semiconductor wafer;
locally etching the layer of the first adhesive material so as to form local crowns;
forming electronic chips in the wafer, said electronic chips having peripheries respectively in contact with corresponding local crowns;
singulating the thinned semiconductor wafer at locations of the local crowns to individualize electronic integrated circuit chips equipped on their first face with a corresponding crown, wherein each corresponding crown defines an internal housing;
disposing a second adhesive material in each internal housing; and
fastening each electronic integrated circuit chip onto a corresponding carrier substrate via the second adhesive material.

14. The method according to claim 13, wherein the first adhesive material is an adhesive film, and wherein the second adhesive material is a glue.

15. The method according to claim 13, wherein the first adhesive material is a filling material, and wherein the second adhesive material is a glue.

16. The method according to claim 13, wherein the second adhesive material covers at least between 80% and 90% of a surface of said first face of each electronic integrated circuit chip.

17. The method according to claim 13, wherein the internal housing exposes at least between 80% and 90% of a surface of said first face of the electronic integrated circuit chip and the second adhesive substantially covers said surface that is exposed.

18. The method according to claim 13, further comprising forming at least one lateral opening in each corresponding crown, wherein each lateral opening extends from the internal housing to an outer surface of the corresponding crown.
